(19) United States
(12) Patent Application Publication
(10) Pub. No.: US 2002/0061604 A1
(43) Pub. Date: May 23, 2002

(54) Method for fabricating a ferroelectric or paraelectric metal oxide-containing layer and a memory component therefrom

(76) Inventors: Arkalgud Sitaram, Fishkill, NY (US); Christine Dehm, Nurnberg (DE)

Correspondence Address: LERNER AND GREENBERG, P.A., PATENT ATTORNEYS AND ATTORNEYS AT LAW, Post Office Box 2480, Hollywood, CA, 33022-2480, US

(21) Appl. No.: 10/012,166

(22) Filed: Oct. 26, 2001

(30) Foreign Application Priority Data
Oct. 26, 2000 (DE) 100 53 171.7

(51) Int. Cl. H01L 21/00; H01L 21/8242

(52) U.S. Cl. 438/3; 438/240

(57) ABSTRACT

A method is described in which a metal oxide-containing layer is applied to a substrate and is then exposed to implantation with oxygen ions. A subsequent heat-treatment step can be carried out in an inert atmosphere and with shorter process times, since the oxygen is already present in the metal oxide-containing layer and, moreover, shorter diffusion paths are required for the oxygen to become intercalated in the crystal lattice of the metal oxide-containing layer. Therefore, adjacent layers, such as barrier layers, are less affected by the heat treatment.

### BACKGROUND OF THE INVENTION

Field of the Invention

The invention relates to a method for fabricating a ferroelectric or paraelectric metal oxide-containing layer. In particular, the invention relates to the fabrication of a layer of this type that is used as a ferroelectric or paraelectric capacitor material instead of a dielectric in a storage capacitor of a DRAM memory cell. Dynamic semiconductor memory components (DRAMs) fabricated in microelectronics generally contain a select or a switching transistor and a storage capacitor, in which a dielectric material is inserted between two capacitor plates. The dielectric used usually contains oxide or nitride layers that have a dielectric constant of at most approximately 8. To reduce the size of the storage capacitor and to be able to fabricate nonvolatile memories, “new types” of capacitor materials, such as for example ferroelectric or paraelectric materials with significantly higher dielectric constants, are required. A few of the materials are listed in the publication “Neue Dielektrika für Gbit-Speicherchips” [New Dielectrics for Gbit Memory Chips] by W. Hönlein, Phys. Bl. 55 (1999). By way of example, ferroelectric materials, such as SrBi₂ (Ta, Nb)₂O₉ (SBT or SBTN), Pb (Zr, Ti)O₃ (PZT) or Bi₄Ti₃O₁₂ (BTO) can be used as the dielectric between the capacitor plates for the fabrication of the ferroelectric capacitors for applications in nonvolatile semiconductor memory components with a high integration density of this type. However, it is also possible to use a paraelectric material, such as for example (BaSr) TiO₃ (BST). Wherever the following text refers to ferroelectric materials, this term is also intended to encompass paraelectric materials.

The use of ferroelectric materials for storage capacitors places new demands on the semiconductor process technology. First, these new types of materials can no longer be combined with the traditional electrode material polysilicon. The reason for this is that after the deposition of the ferroelectric material, the latter has to be annealed (“conditioned”), possibly a number of times, in an oxygen-containing atmosphere at temperatures of approximately 550-800° C. To avoid undesirable chemical reactions between the ferroelectric material and the electrodes, it is necessary to use sufficiently temperature-stable and inert electrode materials, such as for example platinum metals, i.e. Pt, Pd, Ir, Rh, Ru or Os, their conductive oxides (e.g. RuO₂) or other conductive oxides, such as LaSrCoOₓ or SrRuO₃. However, the heat treatment of the ferroelectric layer, which is usually carried out in an oxygen-containing atmosphere, results in production defects.

### SUMMARY OF THE INVENTION

It is accordingly an object of the invention to provide a method for fabricating a ferroelectric or paraelectric metal oxide-containing layer and a memory component therefrom which overcomes the above-mentioned disadvantages of the prior art methods of this general type, which can be carried out under tolerable process conditions, in particular with short treatment times and at low temperatures.

With the foregoing and other objects in view there is provided, in accordance with the invention, a method for fabricating a metal oxide-containing layer. The method includes the steps of providing a substrate; applying a layer being either a ferroelectric, metal oxide-containing layer or a paraelectric, metal oxide-containing layer, to the substrate; implanting oxygen in the layer; and carrying out a heat-treatment process.

With the foregoing and other objects in view there is additionally provided, in accordance with the invention, a method for fabricating a metal oxide-containing layer. The method includes the steps of implanting oxygen into a ferroelectric or paraelectric, metal oxide-containing layer or an auxiliary layer adjoining the metal oxide-containing layer; and carrying out a heat-treatment process.

A significant idea of the present invention relates to implanting the oxygen in the metal oxide-containing layer and then activating the oxygen atoms in the layer in the heat-treatment process step. Since the oxygen is already in the layer, during the subsequent heat treatment the oxygen atoms only have to cover short distances in order to be intercalated in the crystal lattice of the layer. Therefore, the duration of the heat treatment can be kept relatively short.

Therefore, it is also conceivable for an auxiliary layer to be applied to the metal oxide-containing layer and for oxygen ions to be implanted only in the auxiliary layer. This may be desirable in order to avoid any damage to the metal oxide-containing layer being caused by the implantation and restricting this to the auxiliary layer, which can be removed again after the heat treatment has been carried out.

A significant advantage of the method according to the invention is that the heat-treatment step can be carried out in an inert atmosphere, since the oxygen is already present in the layer and does not first have to be supplied from an oxygen-containing atmosphere.

For the fabrication of a storage capacitor for a DRAM memory cell, the metal oxide-containing layer is preferably formed by a ferroelectric or a paraelectric material. In the former case, the metal oxide-containing layer preferably contains one of the materials SrBi₂ (Ta, Nb)₂O₉ (SBT or SBTN), Pb (Zr, Ti)O₃ (PZT) or Bi₄Ti₃O₁₂ (BTO). In the latter case, the metal oxide-containing layer contains, for example, the material (BaSr) TiO₃ (BST).

The metal oxide-containing layer may be deposited by a metal-organic deposition (MOD), a metal-organic chemical vapor deposition (MOCVD) or using a sputtering process.

For the fabrication of a storage capacitor, the electrode material used may be a platinum metal, a conductive oxide of a platinum metal or another conductive oxide. In general, the presence of a precious-metal electrode beneath the metal oxide-containing layer leads to an abrupt drop in the implantation profile at the interface of the two layers, since during the implantation the oxygen ions only penetrate to an insignificant extent into the precious-metal electrode, so that they are almost exclusively distributed in the metal oxide-containing layer.

With the ion implantation according to the invention, it is possible to precisely set the oxygen concentration in the metal oxide-containing layer. In most cases, it will be sufficient to carry out a single implantation step with a predetermined dose of oxygen ions and to select the ion energy in such a manner that the frequency distribution of the implanted ions reaches a maximum at approximately halfway through the depth of the layer. If appropriate, however, it is also possible to select a plurality of different ion energies in order to achieve a depth-dependent, homogeneous distribution of the implanted ions from the outset. In the case of any topographic variations being present in the layer, it may also be necessary or desirable for the implantation to be carried out at one or more different predetermined angles and for the wafer to be rotated about the cylinder axis during the implantation.

The method according to the invention can be incorporated as part of a method for the fabrication of a storage capacitor and also a memory component containing the storage capacitor, in particular a DRAM memory cell. In this case, the heat-treatment step may also be carried out in a very late stage of component fabrication, for example immediately before the fabrication of the contact metallization.

With the foregoing and other objects in view there is additionally provided, in accordance with the invention, a method for fabricating a storage capacitor. The method includes the steps of providing a substrate functioning as a first electrode; applying a ferroelectric or paraelectric, metal oxide-containing layer to the substrate; implanting oxygen into the metal oxide-containing layer; applying a second electrode to the metal oxide-containing layer; and carrying out a heat-treatment process. Alternatively, the heat treating process can be carried out after the oxygen has been implanted and before the second electrode is formed.

With the foregoing and other objects in view there is further provided, in accordance with the invention, a method for fabricating a memory component. The method includes the steps of providing a substrate; forming a switching transistor on the substrate; applying an insulation layer to the switching transistor; applying a first electrode above the insulation layer; applying a ferroelectric or paraelectric, metal oxide-containing layer to the first electrode; implanting oxygen in the metal oxide-containing layer; carrying out a heat-treatment process; and applying a second electrode to the ferroelectric, metal oxide-containing layer. Alternatively, the heat treatment process can be carried out after the second electrode is formed.

Other features which are considered as characteristic for the invention are set forth in the appended claims.

Although the invention is illustrated and described herein as embodied in a method for fabricating a ferroelectric or paraelectric metal oxide-containing layer and a memory component therefrom, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1A is a diagrammatic, cross-sectional view of a conventional DRAM memory cell in a stacked configuration;

FIG. 1B is a partial, cross-sectional view of a detailed excerpt illustrating a storage capacitor and the way in which contact is made in the conventional DRAM memory cell; and

FIGS. 2A and 2B are diagrammatic, cross-sectional views of a storage capacitor which is fabricated in accordance with the invention after individual method steps in accordance with an exemplary embodiment of the present invention.

### DESCRIPTION OF THE PREFERRED EMBODIMENTS

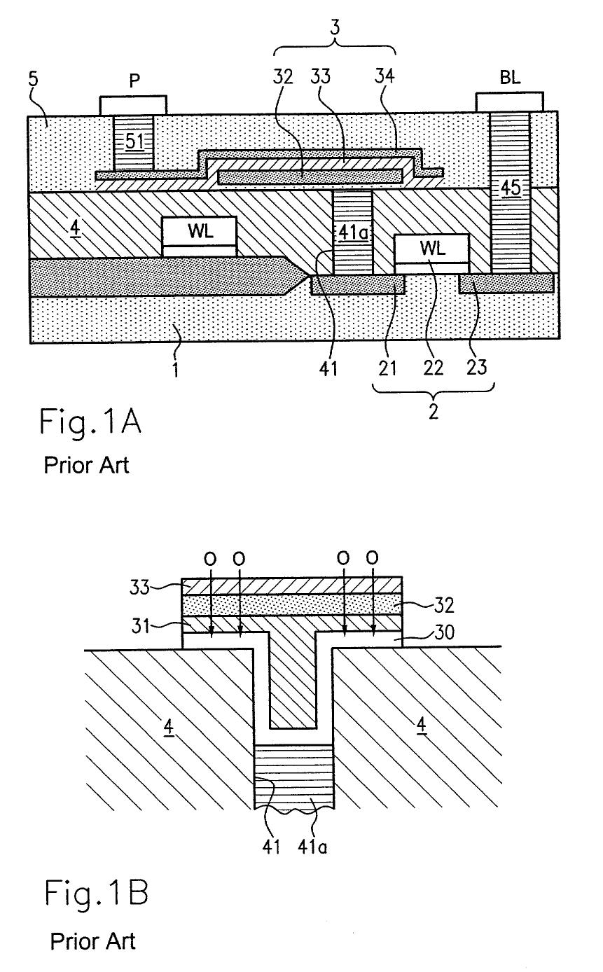

Referring now to the figures of the drawing in detail and first, particularly, to FIG. 1A thereof, there is shown a cross-sectional view of a conventional DRAM memory cell configured as a stacked cell. In the configuration of the memory cell, a switching transistor 2 and a storage capacitor 3 are disposed substantially directly above one another. A lower electrode 32 of the storage capacitor 3 together with a drain region 21 of the MOS transistor 2 being electrically connected to one another by a through-contact 41 which is filled with a plug 41a of an electrically conductive material (e.g. polycrystalline silicon) and is etched through an insulation layer 4.

First, the MOS transistor 2 is fabricated on a semiconductor substrate 1. The drain region 21 and a source region 23 are formed by doping, between which regions there is a channel, a conductivity of which can be controlled by a gate 22 disposed above the channel. The gate 22 may be formed by or connected to a word line WL of the memory component. The source region 23 is connected to a bit line BL of the memory component. The MOS transistor 2 is then covered with a planarizing insulation layer 4, for example with an oxide, such as SiO₂. The storage capacitor 3 is formed on the insulation layer 4. The lower electrode 32 being applied and patterned, which lower electrode 32 is electrically connected to the drain region 21 of the MOS transistor 2 through the through-contact 41 which is filled with the plug 41a. Then, a metal oxide-containing layer 33 of a ferroelectric material is deposited on the lower electrode 32, which layer forms the capacitor material. An upper electrode 34 is deposited over the entire surface of the metal oxide-containing layer 33 and is patterned. Finally, the structure obtained is in turn covered by a second planarizing insulation layer 5, for example an oxide layer, such as SiO₂. A further through-contact 51 is formed in the layer 5, through which through-contact the upper electrode 34 of the storage capacitor 3 can be connected to an outer electrical connection P (common capacitor plate) by a suitable conductive material. The source region 23 of the MOS transistor 2 is connected to the bit line BL as a result of a through-contact 45, which extends through both insulation layers 4 and 5, being formed and filled with a conductive material, such as polycrystalline silicon.

A titanium or titanium nitride layer 30 and an oxygen barrier layer 31 are formed between the polycrystalline silicon of the through-contact 41 and the lower electrode layer 32 of the storage capacitor 3. This is not shown in FIG. 1A, in order for the overall illustration to be clearer. FIG. 1B shows a detailed excerpt from FIG. 1A, illustrating the formation of the intermediate layers. The through-contact 41 is only filled with the plug 41a of polysilicon to a certain height, or after it has been completely filled, some of the plug 41a is removed again using an etching process. Then, a Ti layer or a TiN layer or a Ti/TiN double layer 30 is deposited. The oxygen barrier layer 31, which may consist, for example, of an Ir layer, an IrO layer or an Ir/IrO double layer, which fills up the through-contact 41 and which planarizes the structure, is applied to the Ti layer 30. In principle, the barrier layers 30 and 31 may also be formed by other materials, but they must in any event be electrically conductive, in order to make electrical contact with the lower electrode layer 31. The Ir layer 31 is intended to prevent oxygen reaching the polycrystalline silicon of the plug 41a and forming an electrically insulating SiO₂ layer on the surface during thermal oxidation or the like which forms part of the fabrication of the capacitor. Iridium (Ir) or iridium oxide (IrO) have the advantage of being able to absorb oxygen without its electrical conductivity being significantly impaired. The Ti intermediate layer below it serves as a suitable transition layer, since it forms a low-resistance titanium silicide boundary layer with the polycrystalline silicon, and it represents a suitable nucleation layer for the Ir layer.

Then, the lower electrode layer 32 is formed, for example from Pt, on the barrier layer 31, and the ferroelectric layer 33, such as for example an SBT layer, is applied to the lower electrode layer 32. The subsequent heat-treatment step is carried out in an oxygen-containing atmosphere. The process is based on oxygen from the surrounding atmosphere penetrating into the SBT layer 33, where it is intercalated in the crystal lattice of the SBT layer 33. Therefore, the process requires not only a high temperature, as mentioned in the introduction, but also a relatively long treatment time. The barrier layers 30 and 31 are often unable to withstand the prolonged heat-treatment time. This leads to the oxygen penetrating through the oxygen barrier layer 31 (see arrow in FIG. 1) and oxidizing the titanium material of the Ti layer 30, so that a thin, insulating TiO layer is formed. Since titanium is highly susceptible to oxidation, even relatively small quantities of oxygen may be sufficient to form the TiO layer. This makes the component unusable, since the electrical contact between the lower electrode layer 31 and the drain region 21 of the MOS transistor 2 is interrupted.

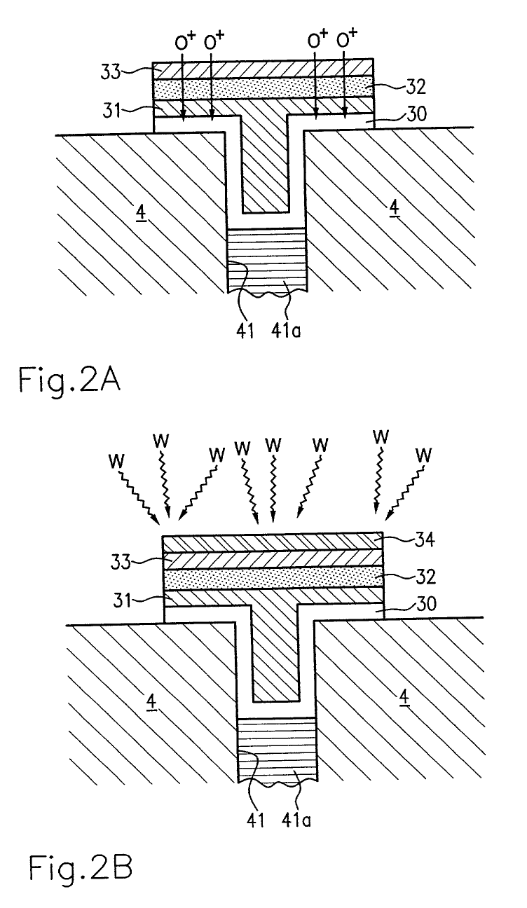

As shown in FIG. 2A, and according to the invention, the Ti layer, the TiN layer or the Ti/TiN double layer 30 is deposited into an upper section of the through-contact 41 which has been formed in the insulation layer 4, so that it lines the walls of the through-contact 41 in the upper section and initially covers the upper surface of the insulation layer 4, before being patterned together with other layers in a subsequent method step. Then, as has likewise already been described, the Ir layer, the IrO layer or the Ir/IrO double layer 31 is applied as the oxygen barrier. Next, the first, lower electrode layer 32, for example of platinum, is deposited on the latter.

The metal oxide-containing layer 33, in the present case the SBT layer, is deposited on the electrode layer 32. The deposition may optionally be carried out by a metal-organic deposition (MOD) method or a metal-organic chemical vapor deposition (MOCVD) method.

Then, as indicated by the arrows O⁺, an implantation of oxygen ions into the SBT layer 33 is carried out with a predetermined ion dose and energy.

Then, as shown in FIG. 2B, a second, upper electrode layer 34 can be deposited on the SBT layer 33. Only then—as indicated by the arrows W—is the heat-treatment step carried out in an inert atmosphere in a conventional furnace. Since the oxygen is already present in the SBT layer 33, the duration of the heat treatment can be reduced compared to the conventional process. By way of example, the heat treatment can be carried out as a rapid thermal annealing (RTA) process that is known per se in the prior art. Under certain circumstances, it is also possible to set a lower temperature compared to the temperature required in the conventional annealing process.

A further advantage becomes clear from FIG. 2B. The heat-treatment step does not have to be carried out immediately after the SBT layer 33 has been formed. In the exemplary embodiment illustrated, the heat treatment is carried out after the formation of the second, upper electrode layer 34. However, if desired it may also be carried out at an even later stage of component fabrication.

We claim:

1. A method for fabricating a metal oxide-containing layer, which comprises the steps of:
implanting oxygen into one of a ferroelectric, metal oxide-containing layer and an auxiliary layer adjoining the ferroelectric, metal oxide-containing layer; and
carrying out a heat-treatment process.

2. A method for fabricating a metal oxide-containing layer, which comprises the steps of:
providing a substrate;
applying a ferroelectric, metal oxide-containing layer to the substrate;
applying an auxiliary layer to the ferroelectric, metal oxide-containing layer;
implanting oxygen in one of the ferroelectric, metal oxide-containing layer and the auxiliary layer; and
carrying out a heat-treatment process.

3. The method according to claim 2, which comprises carrying out the heat-treatment process in a substantially inert atmosphere.

4. A method for fabricating a storage capacitor, which comprises the steps of:
providing a substrate functioning as a first electrode;
applying a ferroelectric, metal oxide-containing layer to the substrate;
implanting oxygen into the ferroelectric, metal oxide-containing layer;
applying a second electrode to the ferroelectric, metal oxide-containing layer; and
carrying out a heat-treatment process.

5. The method according to claim 4, which comprises forming the first electrode and the second electrode from a material selected from the group consisting of Pt, Pd, Ir, Rh, Ru, Os, a conductive oxide of a platinum metal, and a conductive oxide.

6. A method for fabricating a memory component, which comprises the steps of:
providing a substrate;
forming a switching transistor on the substrate;
applying an insulation layer to the switching transistor;
applying a first electrode above the insulation layer;
applying a ferroelectric, metal oxide-containing layer to the first electrode;
implanting oxygen in the ferroelectric, metal oxide-containing layer;
carrying out a heat-treatment process; and
applying a second electrode to the ferroelectric, metal oxide-containing layer.

7. A method for fabricating a metal oxide-containing layer, which comprises the steps of:
implanting oxygen into one of a paraelectric, metal oxide-containing layer and an auxiliary layer adjoining the paraelectric, metal oxide-containing layer; and
carrying out a heat-treatment process.

8. The method according to claim 7, which comprises performing the heat-treatment process in a substantially inert atmosphere.

9. A method for fabricating a metal oxide-containing layer, which comprises the steps of:
providing a substrate;
applying a paraelectric, metal oxide-containing layer to the substrate;
applying an auxiliary layer to the paraelectric, metal oxide-containing layer;
implanting oxygen into one of the paraelectric, metal oxide-containing layer and the auxiliary layer; and
carrying out a heat-treatment process.

10. A method for fabricating a storage capacitor, which comprises the steps of:
providing a substrate functioning as a first electrode;
applying a ferroelectric, metal oxide-containing layer to the substrate;
implanting oxygen in the ferroelectric, metal oxide-containing layer;
carrying out a heat-treatment process; and
applying a second electrode to the ferroelectric, metal oxide-containing layer.

11. A method for fabricating a storage capacitor, which comprises the steps of:
providing a substrate functioning as a first electrode;
applying a paraelectric, metal oxide-containing layer to the substrate;
implanting oxygen in the paraelectric, metal oxide-containing layer; applying a second electrode to the paraelectric, metal oxide-containing layer; and
carrying out a heat-treatment process.

12. The method according to claim 11, which comprises forming the first electrode and the second electrode from a material selected from the group consisting of Pt, Pd, Ir, Rh, Ru, Os, a conductive oxide of a platinum metal, and a conductive oxide.

13. A method for fabricating a storage capacitor, which comprises the steps of:
providing a substrate functioning as a first electrode;
applying a paraelectric, metal oxide-containing layer to the substrate;
implanting oxygen in the paraelectric, metal oxide-containing layer;
carrying out a heat-treatment process; and
applying a second electrode to the paraelectric, metal oxide-containing layer.

14. A method for fabricating a memory component, which comprises the steps of:
providing a substrate;
forming a switching transistor on the substrate;
applying an insulation layer to the switching transistor;
applying a first electrode above the insulation layer;
applying a paraelectric, metal oxide-containing layer to the first electrode;
implanting oxygen in the paraelectric, metal oxide-containing layer;
carrying out a heat-treatment process; and
applying a second electrode to the paraelectric, metal oxide-containing layer.

15. The method according to claim 14, which comprises forming the memory component as a dynamic random access memory cell.

16. A method for fabricating a metal oxide-containing layer, which comprises the steps of:
providing a substrate;
applying a layer selected from the group consisting of a ferroelectric, metal oxide-containing layer and a paraelectric, metal oxide-containing layer, to the substrate; implanting oxygen in the layer; and
carrying out a heat-treatment process.
